(19) United States
(12) Patent Application Publication
(10) Pub. No.: US 2007/0176305 A1
(43) Pub. Date: Aug. 2, 2007

(54) Alignment mark and overlay inspection mark

(75) Inventor: Suguru Sasaki, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO.,LTD., Tokyo (JP)

(21) Appl. No.: 11/600,213

(22) Filed: Nov. 16, 2006

(30) Foreign Application Priority Data
Feb. 2, 2006 (JP) 2006-026322

(51) Int. Cl. H01L 23/544; H01L 21/00

(52) U.S. Cl. 257/797; 438/462; 257/E23.179

(57) ABSTRACT

An alignment mark is formed on an underlying layer and disposed on a region in which a semiconductor device is not formed. The alignment mark includes a plurality of strip-shaped patterns detectable by an optical imaging device. The patterns have long axes and short axes. The patterns are arranged in a matrix of rows and columns in such a manner that the long axes are substantially perpendicular to the direction of the alignment adjustment.

### BACKGROUND OF THE INVENTION

This invention relates to a manufacturing method of a semiconductor device, and particularly relates to an alignment mark and an overlay inspection mark employed in the manufacturing method for enhancing the overlay accuracy of resist patterns (i.e., resist masks) used in a plurality of photolithography processes.

In the manufacturing process of the semiconductor device (i.e., a wafer process), several tens layers of resist patterns are formed by photolithography to manufacture one kind of semiconductor device.

A resist pattern (having a predetermined pattern) is formed by forming a resist layer on the entire surface of a wafer and by patterning the resist layer in an exposing process using an exposing device.

For example, in order to form a second pattern on a first pattern (having been patterned using a first resist pattern), it is necessary to accurately align a second resist-pattern with the first pattern.

Generally, in order to accurately align the upper resist pattern with the lower pattern, an alignment mark of a predetermined shape is formed on a wafer.

The alignment mark is formed on a margin region on the wafer outside a chip region (i.e., a semiconductor element forming region). In other words, the alignment mark is formed on a region in which a device pattern such as a wiring pattern (related to the essential function of the semiconductor device) is not formed, i.e., a region in which scrub lines are formed.

The alignment mark is detected using an imaging device mounted on the exposing device, before the exposing process of the upper resist pattern is carried out. Then, the exposing device adjusts the exposing position in accordance with the detected coordinates (X-coordinate and Y-coordinate) of the alignment mark. Then, the exposing process is carried out, so that the upper resist pattern is patterned and is overlaid on the lower pattern.

The alignment mark is generally detected using an optical imaging device (i.e., an imaging element) such as CCD (Charge Coupled Device) or laser.

Further, there is known an overlay inspection mark formed in a similar manner to the alignment mark.

The overlay inspection mark is a mark for inspecting whether the resist pattern is accurately formed on the predetermined position. The overlay inspection mark includes a first mark and a second mark. The first mark is formed on the lower (underlying) layer. The second mark is formed in the exposing process of the resist pattern, while adjusting the exposing position according to the alignment mark on the wafer. The overlay accuracy is inspected based on whether the first mark and the second mark are accurately aligned with each other.

Generally, the overlay inspection mark (i.e., the first mark and the second mark) is optically detected using an optical imaging device such as CCD.

If the position of the second mark deviates from the position of the first mark beyond the allowable range, the resist pattern (including the second mark) is completely removed. Then, the exposing position of the exposing device is adjusted according to the detected deviation, and the exposing process is carried out again.

Hereinafter, the conventional alignment mark and the overlay inspection mark will be described with reference to FIGS. 7A, 7B and 8.

FIG. 7A is a plan view showing the conventional alignment mark as seen from above. The alignment mark shown in FIG. 7A is formed on the wafer for the alignment adjustment in the direction of X-axis. FIG. 7B is a photographic view of the conventional alignment mark. FIG. 8 is a plan view showing the conventional overlay inspection mark as seen from above.

As shown in FIG. 7A, the conventional alignment mark 110 includes a plurality of linear patterns (in this example, 18 linear patterns) 112 formed on the wafer 114. The linear patterns 112 are strip-shaped and have long axes 112a defining the length L1 and short axes 112b defining the width W1. The axes 112a and 112b are perpendicular to each other.

The linear patterns 112 are so arranged that the long axes 112a are directed in the direction of Y-axis. The linear patterns 112 are disposed at constant intervals and in parallel to each other. The linear patterns 112 are disposed at pitches Px1 in the direction of X-axis, so that the linear patterns 112 are distanced from each other by Px1-W1. The alignment mark 110 is used for the alignment adjustment of the resist pattern in the direction of X-axis.

The examples of the dimensions of the alignment mark 110 are as follows. The length L1 of the long axis 112a is in a range from 50 μm to 100 μm. The width L2 of the short axis 112b is in a range from 0.6 μm to 6 μm. The arrangement pitch Px1 of the patterns 112 is in a range from 6 μm to 12 μm.

However, even when the above described alignment mark is used, if the same resist pattern includes the device pattern and the alignment mark that are different from each other in shape, size, density or the like, the deviation of the resist patterns may occur due to the difference in shape, size, density or the like.

In order to solve this problem, it is proposed to use the alignment mark and the overlay inspection mark whose size and shape are almost the same as the device pattern formed in the resist pattern, as disclosed in, for example, Japanese Laid-Open Patent Publication No. 2002-64055.

As shown in FIG. 8, the conventional overlay inspection mark 120 is constituted by a combination of two kinds of marks, i.e., a first mark 122 and a second mark 124, which are formed on different patterning processes.

The first mark 122 includes four strip-shaped linear marks 122X. The linear marks 122X have long axes 122a defining the length L3 and short axes 122b defining the width W3. The axes 122a and 122b are perpendicular to each other.

The linear marks 122X are disposed on four sides of a square disposed around a center point C so that a pair of linear marks 122X face each other and another pair of linear marks 122X face each other. A center point 122c of one linear mark 122, another center point 122c of the opposite linear mark 122, and the above described center point C are aligned on a straight line.

Two linear marks 122X extend along X-axis and face each other in the direction of Y-axis, and the other two linear marks 122X extend along Y-axis and face each other in the direction of X-axis.

The second mark 124 has a rectangular shape and has two sides of the length A3 along X-axis and two sides of the length B3 along Y-axis.

The second mark 124 is formed as a part of the resist pattern. As a result of the alignment adjustment, the second mark 124 is disposed in the vicinity of the center point C surrounded by four linear marks 122X of the first marks 122.

The overlay accuracy of the resist pattern (including the second mark 124) is determined based on the positional relationship between the first mark 122 and the second mark 124. To be more specific, the overlay accuracy is evaluated based on the distances between the respective sides (i.e., edges of the rectangle) of the second mark 124 and corresponding linear marks 122X of the first mark 122 facing the respective sides of the second mark 124. In other words, the overlay accuracy is evaluated based on whether the distances between the sides of the second mark 124 and the corresponding linear marks 122X are within an allowable range or not.

In order to enable more accurate and easier recognition of the overlay inspection mark, there is proposed an overlay inspection mark composed of a plurality of grooves having different widths formed on a film disposed on the semiconductor substrate, as disclosed in, for example, Japanese Laid-Open Patent Publication No. 2003-234272.

Moreover, in order to prevent the generation of void at the corners of the rectangular overlay inspection mark, there is proposed an overlay inspection mark whose corners (where the void tends to generate) are removed, as disclosed in Japanese Laid-Open Patent Publication No. 2005-086091.

In the above described conventional arts, the length (width) and the pitch of the alignment mark in the alignment adjustment direction (along of X axis or Y axis) are suitably adjusted in accordance with detection accuracy. However, the length of the alignment mark in the direction perpendicular to the alignment adjustment direction has not been considered to cause problems, as long as the overlay accuracy required to enable the alignment adjustment can be obtained.

Similarly, the length of the overlay inspection mark has not been considered to cause problems.

In the manufacturing process of the semiconductor device such as a ferroelectric memory, it is necessary to perform a heat treatment (i.e., a recovery annealing) at high temperature, for example, in a range from 600° C. to 800° C. under oxygen atmosphere, after the patterning of the ferroelectric capacitor is completed.

If the alignment mark and the overlay inspection mark are long, the heat treatment may cause the following problems.
(1) The heat treatment causes a thermal expansion or shrinkage of an upper film and/or a lower film (or substrate) In such a case, the alignment mark and/or the overlay inspection mark may not resist a stress on the surface of the film, or the adhesive force between the mark and the surface of the film may decrease, with the result that the alignment mark and/or the overlay inspection mark may be separated from the film or broken.
(2) The heat treatment may cause the alignment mark and/or the overlay inspection mark to interfere with the thermal expansion or shrinkage of the upper film and/or the lower film, with the result that a crack may be formed as indicated by mark CR in FIG. 7B. The crack may reach the chip region from the margin region in which the alignment mark and the overlay inspection mark are provided. In such a case, the essential function of the semiconductor device may be degraded.

### SUMMARY OF THE INVENTION

An object of the present invention is to provide a manufacturing method capable of preventing the breakage or separation of an alignment mark and an overlay inspection mark, preventing the generation of crack, and enhancing the overlay accuracy.

The present invention provides an alignment mark formed on an underlying layer and disposed on a region in which a semiconductor element is not formed. The alignment mark includes a plurality of strip-shaped patterns detectable by an optical imaging device. The patterns have long axes and short axes, and the patterns are arranged in a matrix of rows and columns in such a manner that the long axes are substantially perpendicular to the direction of the alignment adjustment.

The present invention also provides an overlay inspection mark formed on an underlying layer and disposed on a region in which a semiconductor element is not formed. The overlay inspection mark includes a first mark and a second mark both of which are detectable by an optical imaging device. The first mark includes four linear marks each of which includes a plurality of strip-shaped dot marks having long axes and short axes. The dot marks of each of the linear marks are so disposed that long axes thereof are directed in the same direction. The linear marks are disposed on four sides of a square in such a manner that two of the linear marks face parallel to each other across a center point of the square, and the other two of the linear marks face parallel to each other across the center point. The second mark has shape and size that enable the measurement of a positional relationship between the second mark and the first mark.

In the above described alignment mark, the lengths of the patterns (along the long axes) are short, and the patterns are separate from each other. In the above described overlay inspection mark, the lengths of the dot marks (along the long axes) are short, and the dot marks are separate from each other. Therefore, even when the upper layer and/or the lower layer (for example, an insulation film) is thermally expanded or shrunk by a heat treatment in the manufacturing process, the stress applied to the alignment mark and the overlay inspection mark can be reduced as a whole. Accordingly, it becomes possible to prevent the separation of the alignment mark and the overlay inspection mark from the surface of the layer, to prevent the breakage of the alignment mark and the overlay inspection mark, and to prevent the generation of the crack that degrades an essential function of the semiconductor device. As a result, the yield rate of the semiconductor device can be enhanced.

### BRIEF DESCRIPTION OF THE DRAWINGS

In the attached drawings:

FIG. 1A is a schematic plan view showing an alignment mark according to the first embodiment of the present invention as seen from above;

FIG. 1B is a photographic view showing the alignment mark of FIG. 1A;

FIG. 2 is a graph showing a measured wave profile of the alignment mark of FIG. 1A;

FIG. 3A is a schematic plan view showing an overlay inspection mark according to the first embodiment of the present invention;

FIG. 3B is a photographic view showing the overlay inspection mark of FIG. 3A;

FIGS. 4A and 4B are graphs showing signal intensity detected in an inspection process;

FIG. 5A is a schematic plan view showing an alignment mark according to the second embodiment of the present invention as seen from above;

FIG. 5B is a schematic plan view showing an overlay inspection mark according to the second embodiment of the present invention;

FIG. 6 is a schematic sectional view showing a ferroelectric memory device;

FIG. 7A is a schematic plan view showing a conventional alignment mark;

FIG. 7B is a photographic view showing the conventional alignment mark; and

FIG. 8 is a schematic plan view showing a conventional overlay inspection mark.

### DETAILED DESCRIPTION OF THE PREFERRED EMBODIMENT

Embodiments of the present invention will be described with reference to the attached drawings. Shapes, sizes and positions of respective components are schematically shown in the attached drawings for purpose of illustration, but the present invention is not limited to the shapes, sizes and positions shown in the drawings. Materials, conditions, numerical examples or the like described in the following description are only preferred examples, but the present invention is not limited to these features. In the attached drawings, the same components are assigned the same reference numerals, and duplicate explanation will be omitted.

### First Embodiment

### <Configuration Example of Alignment Mark>

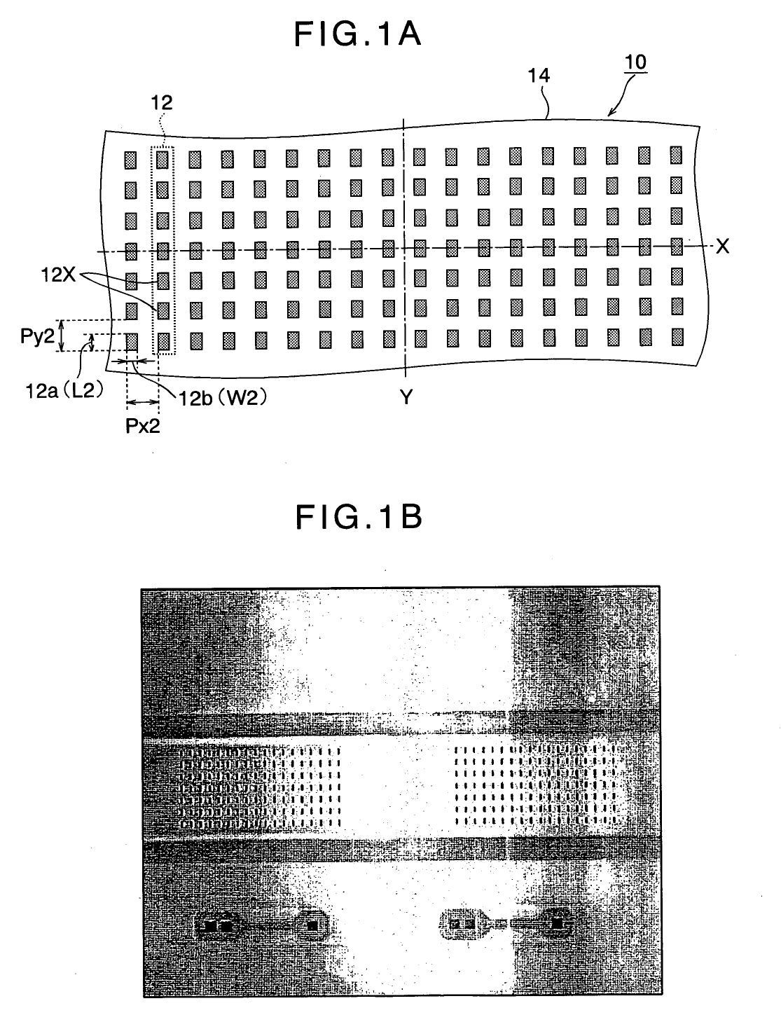

A configuration example of an alignment mark of the first embodiment of the present invention will be described with reference to FIG. 1. The configuration example is intended to prevent the generation of the crack in the heat treatment. In this example, the alignment mark is formed at the same time as the formation of tungsten (W) plugs so that the alignment mark has the same structure as the tungsten plugs. Therefore, the alignment mark of the first embodiment is particularly suitable for alignment adjustment of a resist mask used after the forming process of the tungsten plugs.

FIG. 1A is a schematic plan view showing the alignment mark of the first embodiment as seen from above. FIG. 1B is a photographic view of the alignment mark taken by optical microscope at the magnification of 50 times.

The configuration example of the alignment mark used for the alignment adjustment in the direction of X-axis will be described. The alignment mark 10 includes linear array patterns 12 arranged along X-axis, and each linear array pattern 12 is further divided into a plurality of patterns. To be more specific, each linear array pattern 12 includes a plurality of patterns 12X arranged along Y-axis. The structure of the linear array pattern 12 will be described below.

As shown in FIGS. 1A and 1B, the alignment mark 10 includes a plurality of linear array patterns 12. In this example, the alignment mark 10 includes 18 linear array patterns 12. The linear array patterns 12 are arranged in the direction of X-axis at constant intervals.

Each linear array pattern 12 is divided into a plurality of patterns 12X. In this example, each linear array pattern 12 includes 7 patterns 12X.

Each pattern 12X is strip-shaped, and has a longer axis 12a defining the length L2 and a shorter axis 12b defining the width W2.

The patterns 12X are so disposed that the longer axes 12a extend in the direction of Y-axis. The patterns 12X are disposed parallel to each other and at constant intervals. To be more specific, the patterns 12X are disposed at the pitch Px2 in the direction of X-axis, so that the patterns 12X are distanced from each other by Px2-W2 in the direction of X-axis. Further, the patterns 12X are disposed at the pitch Py2 in the direction of Y-axis, so that the patterns 12X are distanced from each other by Py2-L2 in the direction of Y-axis. In other words, the patterns 12X are disposed in a matrix of 7 rows and 18 columns.

The size of the linear array pattern 12 will be described below. If the length L2 of each pattern 12X is longer than 10 μm, there is a possibility that a layer on which the patterns 12X are formed can not resist the expansion of the patterns 12X so that a crack may be formed on the layer. Therefore, the length L2 of each pattern 12X is preferably shorter than or equals to 10 μm.

Practically, the length L2 of each pattern 12X is preferably, for example, 4 μm, with a margin of resolution error at the current process node and a film residue left after the etching. In this case, the width W2 of each pattern 12X is preferably, for example, 1 μm.

As the distance between the adjacent patterns 12X in the direction of the longer axes 12a (i.e., Y-axis) decreases, the signal intensity also increases. In consideration of the above described margin, the distance between the adjacent patterns 12X in the direction of the longer axes 12a is preferably, for example, 4 μm. In this case, the distance between the adjacent patterns 12X in the direction of the shorter axes 12b is preferably, for example, 5 μm.

The distances Px2-W2 and Py2-L2 are not limited to the above described examples, but can be arbitrarily determined in consideration of the process node or the like, as long as the length L2 of the pattern 12X is shorter than or equals to 10 μm.

When the alignment adjustment is carried out using the exposing device, the entire alignment mark 10 is imaged by an optical imaging device such as CCD, and the signal intensity is measured based on the obtained image, so that the position of the alignment mark 10 is specified.

As described above, when the alignment adjustment in the direction of X-axis is carried out, the position of the alignment mark 10 is specified in such a manner that signal intensity is averaged in the direction of Y-axis.

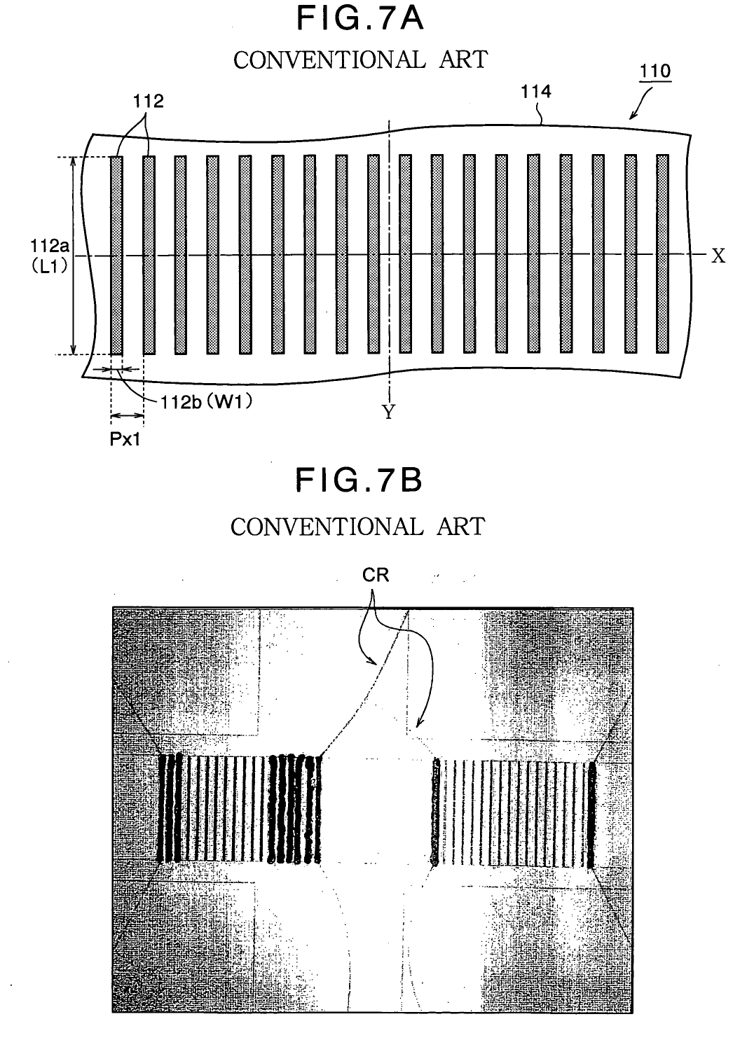

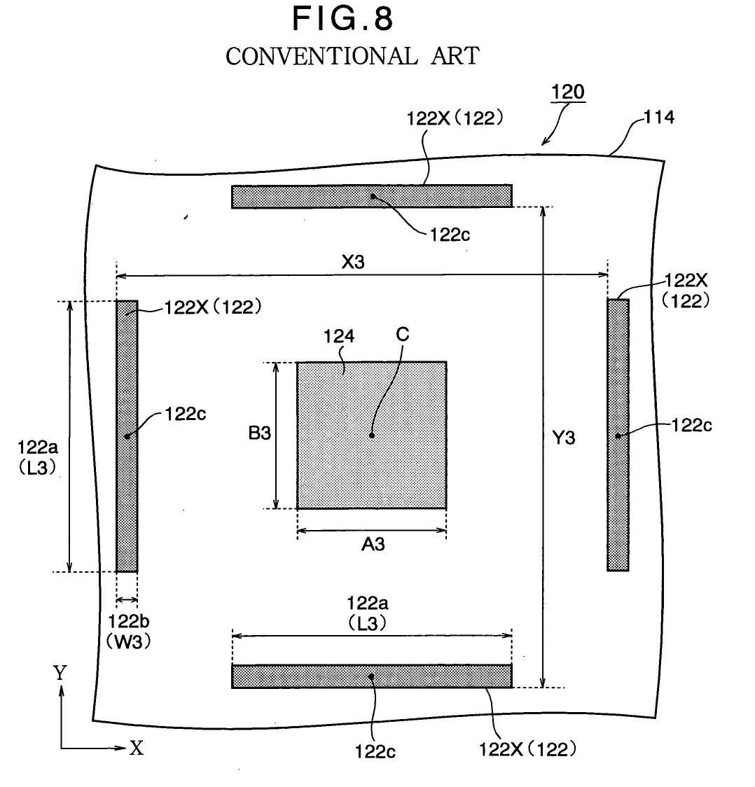

In this regard, since the signal intensity is averaged in the direction of Y-axis, the contrast of the signal intensity hardly decreases, compared with the conventional alignment mark whose patterns are linearly consecutive (see FIG. 7A).

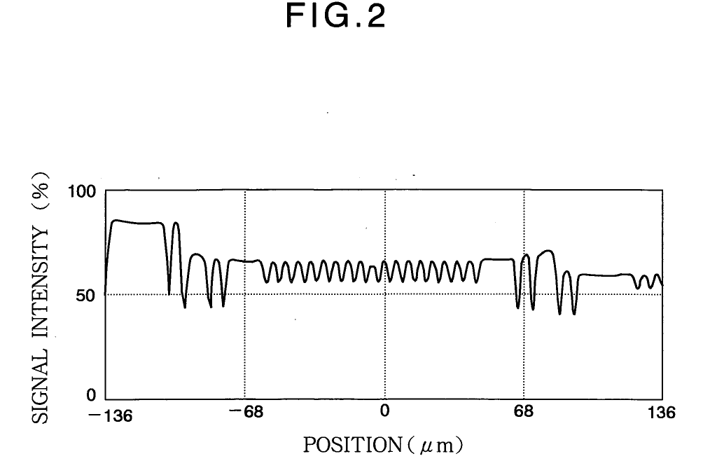

FIG. 2 is a graph showing a measured wave profile of the signal intensity when the alignment mark 10 is used. The signal intensity of FIG. 2 is measured and recorded by a detector provided in the exposing device.

The alignment mark 10 of FIG. 1 includes 18 linear array patterns 12. The wave profile shown in FIG. 2 has downwardly convex peaks corresponding to the linear array patterns 12 in an area from −68 μm to 68 μm along the horizontal axis (i.e., X-axis).

The ratio of the signal intensity of the alignment mark 10 of the first embodiment to that of the conventional alignment mark is 0.86, in accordance with the ratio of the area of the alignment mark 10 to the area of the conventional alignment mark. As seen from the graph of FIG. 2, it is understood that the alignment mark 10 has a sufficient signal intensity to specify the position of the alignment mark 10.

As described above, the linear array patterns 12 of the alignment mark 10 are divided into the small-sized patterns 12X. Therefore, even when the heat treatment is carried out in the manufacturing process of the semiconductor device, it becomes possible to prevent the breakage or separation of the alignment mark 10 or the layer (on which the alignment mark is formed) due to the thermal expansion of the alignment mark 10. Accordingly, the exposing process can be carried out effectively and accurately. Moreover, since the breakage of the layer can be prevented, the yield rate of the semiconductor device can be enhanced.

### <Configuration Example of Overlay Inspection Mark>

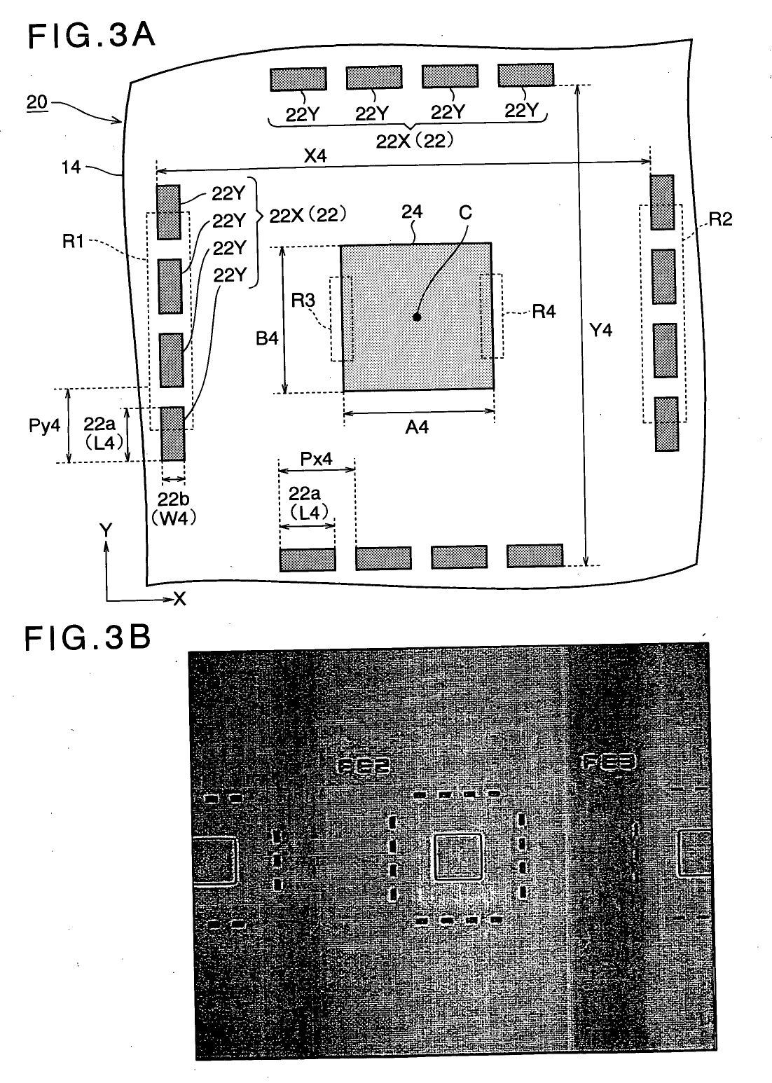

A configuration example of an overlay inspection mark will be described with reference to FIG. 3A. The configuration example of the overlay inspection mark is intended to prevent the generation of the crack in the heat treatment process.

FIG. 3A is a schematic plan view showing the overlay inspection mark as seen from above. FIG. 3B is a photographic view showing the overlay inspection mark taken by optical microscope at the magnification of 50 times.

As shown in FIGS. 3A and 3B, the overlay inspection mark 20 is constituted by a combination of two kinds of marks, i.e., a first mark 22 and a second mark 24, formed on different patterning processes.

In this configuration example, the first mark 22 includes four linear marks 22X. The four linear marks 22X are disposed on four sides of a square having a center point C. A pair of linear marks 22X face parallel to each other, and another pair of linear marks 22X face parallel to each other.

The pair of linear marks 22X are arranged along X-axis, and the other pair of linear marks 22X are arranged along Y-axis.

The distance X4-W4 between the linear marks 22X that face each other in the direction of X-axis across the center portion C is the same the distance Y4-W4 between the other linear marks 22X that face each other in the direction of Y-axis across the center portion C.

Each linear mark 22X includes a plurality of dot marks 22Y. In this example, each linear mark 22X includes 4 dot marks 22Y.

Each dot mark 22Y is strip-shaped, and has a long axis 22a defining the length L4 and a short axis 22b defining the width W4.

Four dot marks 22Y constituting each linear mark 22X are linearly arranged on a straight line so that the long axes 22a are directed is the direction of X-axis or Y-axis.

The dot marks 22Y constituting each linear mark 22X arranged along Y-axis are disposed at the pitch Py4, and are distanced from each other by Py4-L4. The dot marks 22Y constituting each linear mark 22x arranged along X-axis are disposed at the pitch Px4, and are distanced from each other by Px4-L4.

The second mark 24 is rectangular-shaped, and has two sides defining the length A4 extending in the direction of X-axis and two sides defining the length B4 extending in the direction of Y-axis.

The size of the overlay inspection mark 20 will be described below. If the length L4 of each dot mark 22Y is longer than 10 μm, there is a possibility that the dot marks 22Y may separate from the layer. Therefore, the length L4 of each dot mark 22Y is preferably shorter than or equals to 10 μm.

Practically, the length L4 of each dot mark 22Y is preferably, for example, 4 μm, with a margin of resolution error at the current process node and a film residue left after the etching.

In this case, the width W4 of the each dot mark 22Y is preferably, for example, 2 μm.

The distances Py4-L4 and Px4-L4 between the dot marks 22Y constituting each linear mark 22X is preferably, for example, 4 μm.

If the distance (Py4-L4 or Px4-L4) between the dot marks 22Y is too long, the signal intensity becomes small. If the distance is too short, the dot marks 22Y are too close to each other, and it becomes difficult to prevent the generation of the crack. Therefore, the distance between the dot marks 22Y is preferably double the length L4 of the dot mark 22Y.

In this case, the distance (X4-W4=Y4-W4) between the linear marks 22X that face each other across the center point C is preferably, for example, 40 μm.

The length A4 and the length B4 are preferably the same as each other. Further, the length A4 and the length B4 are preferably, for example, 6.5 μm.

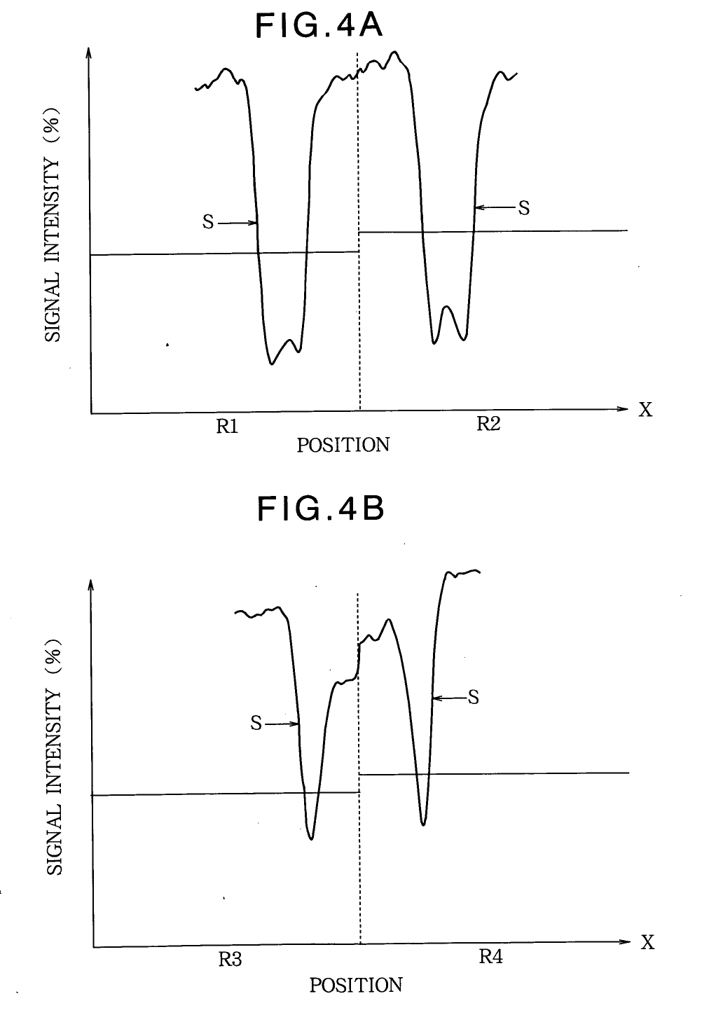

FIGS. 4A and 4B are graphs showing signal intensity measured when the above described overlay inspection mark 20 is used. FIG. 4A shows the signal intensity of box-shaped areas R1 and R2 in FIG. 3A. FIG. 4B shows the signal intensity of box-shaped areas R3 and R4 in FIG. 3A.

Each of the box-shaped areas R1 and R2 has the length of approximately 8 μm in the direction of Y-axis and the length of approximately 2 μm in the direction of X-axis. Each of the box-shaped areas R3 and R4 has the length of approximately 4 μm in the direction of Y-axis and the length of approximately 1.5 μm in the direction of X-axis.

The signal intensity is measured by a conventional overlay measuring apparatus. The arrows “S” in FIGS. 4A and 4B indicate 50% of the threshold of the signal intensity. In FIG. 4A, solid lines drawn parallel to the X-axis indicates 38% of the threshold of the signal intensity. In FIG. 4B, solid lines drawn parallel to the X-axis indicates 28% of the threshold of the signal intensity.

The measurement of the overlay inspection mark on the wafer is repeated approximately 10 times, and the variation in measurement is evaluated.

In the case where the above described overlay inspection mark 20 is used, the variation is within 1 μm. Therefore, it is understood that a sufficient signal intensity and waveform contrast are obtained.

The width W4 and the distances X4-W4 and Y4-W4 are not limited to the above described examples, but can be arbitrarily determined in consideration of the process node or the like, as long as the length L4 of the dot mark 22Y is shorter than or equals to 10 μm.

As described above, the overlay inspection mark 20 is divided into the small-sized dot marks 22Y. Therefore, even when the heat treatment is carried out in the manufacturing process of the semiconductor device, the generation of the crack due to the thermal expansion of the overlay inspection mark 20 can be prevented. Accordingly, the exposing process can be carried out effectively and accurately.

### Second Embodiment

### <Configuration Example of Alignment Mark>

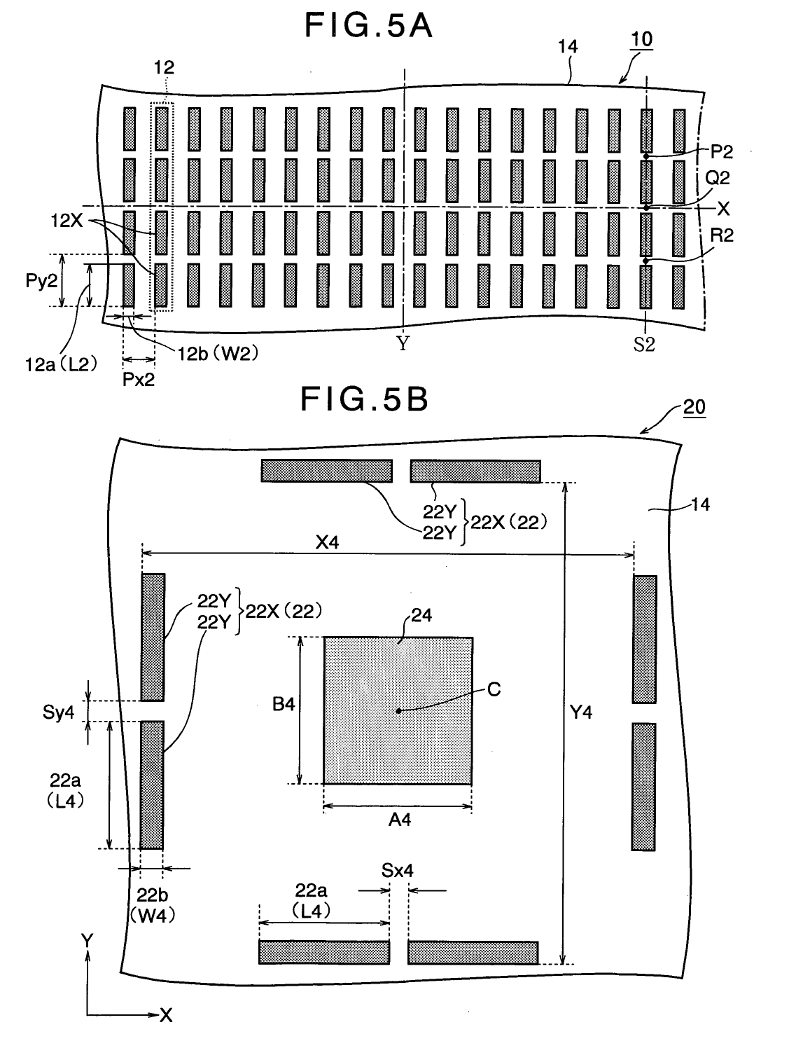

A configuration example of the alignment mark of the second embodiment will be described with reference to FIG. 5A. The configuration example of the alignment mark is intended to prevent the breakage of the alignment mark due to the heat treatment.

FIG. 5A is a schematic plan view of the alignment mark of the second embodiment. FIG. 5B is a schematic view of an overlay inspection mark of the second embodiment as seen from above.

The configuration example of the alignment mark used for the alignment adjustment in the direction of X-axis will be described. The alignment mark 10 is formed at the same time as a ferroelectric capacitor structure in a forming process of the ferroelectric capacitor structure of the ferroelectric memory device. Therefore, the alignment mark 10 of the second embodiment is particularly suitable for alignment adjustment of a resist mask used after the forming process of the ferroelectric capacitor structure.

As shown in FIG. 5A, the alignment mark 10 is formed on a lower layer such as, for example, a margin region (i.e., a region where semiconductor elements are not formed) on a semiconductor wafer 14. The alignment mark 10 includes a plurality of linear array patterns 12. In this configuration example, the alignment mark 10 includes 18 linear array patterns 12. The linear array patterns 12 are arranged at constant intervals so that adjacent linear array patterns 12 face each other in the form of stripes.

Each linear array pattern 12 includes a plurality of patterns 12X disposed linearly at constant intervals. In this configuration example, each linear array pattern 12 includes 4 patterns 12X.

Each of the patterns 12X is strip-shaped, and has a long axis 12a defining the length L2 and a short axis 12b defining the width W2.

The patterns 12X are so configured that the long axes 12a are directed in the direction of Y-axis. The patterns 12X are disposed parallel to each other and disposed at constant intervals. In particular, the patterns 12X are disposed at the pitch Px2 in the direction of X-axis, so that the patterns 12X are distanced from each other by Px2-W2 in the direction of X-axis. The patterns 12X are disposed at the pitch Py2 in the direction of Y-axis, so that the patterns 12X are distanced from each other by Py2-L2 in the direction of Y-axis. In other words, the patterns 12X are disposed in a matrix of 4 rows and 18 columns.

The size of the pattern 12X will be described.

Although data is not shown, it is known that, if the length L2 of each pattern 12X is longer than 16 μm, there is a possibility that the adhesion between the pattern 12X and a surface of the layer (on which the patterns 12X are formed) may be weakened, so that the pattern 12X may break or separate from the surface. Therefore, the length L2 of each pattern 12X is preferably shorter than or equals to 16 μm.

Practically, the length L2 of each pattern 12X is preferably, for example, 15 μm with a margin of resolution error at the current process node and a film residue after the etching process. In this case, the width W2 of each pattern 12X is preferably, for example, 1 μm.

As the distance between the adjacent patterns 12X in the direction of Y-axis decreases, the signal intensity also increases. In consideration of the above described margin, the distance between the adjacent patterns 12X in the direction of Y-axis is preferably, for example, 2 μm. In this case, the distance between the adjacent patterns 12X in the direction of X-axis is preferably, for example, 5 μm.

The width W2 and the distances Px2-W2 and Py2-L2 are not limited to the above described examples, but can be arbitrarily determined in consideration of the process node or the like, as long as the length L2 of the pattern 12X is shorter than or equals to 16 μm.

When the alignment adjustment is carried out using the exposing device, the entire alignment mark 10 is imaged by the optical imaging device such as CCD, and the signal intensity is measured based on the obtained image, so that the position of the alignment mark 10 is specified.

As shown in FIG. 5A, when the alignment adjustment in the direction of X-axis is carried out, the position of the alignment mark 10 is specified in such a manner that signal intensity is averaged in the direction of Y-axis.

In this regard, since the signal intensity is averaged in the direction of Y-axis (i.e., along line S2 shown in FIG. 5A), the contrast of the signal intensity hardly decreases, compared with the conventional alignment mark whose patterns are linearly consecutive (see FIG. 7A).

In this configuration example, the ratio of the signal intensity of the alignment mark 10 to that of the conventional alignment mark is 0.86. The alignment mark 10 has a sufficient signal intensity to specify the position of the alignment mark 10.

As described above, even when the heat treatment is carried out in the manufacturing process of the semiconductor device, and even when the adhesion between the alignment mark 10 and the surface of the layer is weakened, it becomes possible to prevent the breakage or separation of the alignment mark 10. Accordingly, the exposing process can be carried out effectively and accurately.

### <Configuration Example of Overlay Inspection Mark>

A configuration example of an overlay inspection mark of the second embodiment will be described with reference to FIG. 5B. As shown in FIG, 5B, the overlay inspection mark 20 is constituted by a combination of two kinds of marks, a first mark 22 and a second mark 24, formed on different patterning processes.

The linear marks 22X (i.e., the first mark 22) of the second embodiment is different from the linear marks 22X of the first embodiment in that the number of dot marks 22Y (constituting each linear mark 22X) of the second embodiment is half the number of those of the first embodiment.

In this configuration example, the first mark 22 includes 4 linear marks 22X.

The four linear marks 22X are disposed on four sides of a square having a center point C. A pair of linear marks 22X face parallel to each other, and another pair of linear marks 22X face parallel to each other.

The pair of linear marks 22X are arranged along X-axis, and the other pair of linear marks 22X are arranged along Y-axis.

The distance X4-W4 between the linear marks 22X that face each other in the direction of X-axis across the center portion C is the same the distance Y4-W4 between the linear marks 22X that face each other in the direction of Y-axis across the center portion C.

Each of the linear marks 22X includes a plurality of dot marks 22Y. In this configuration example, the linear mark 22X includes 2 dot marks 22Y.

The dot mark 22Y is strip-shaped, and has a long axis 22a defining the length L4 and a short axis 22b defining the width W4.

Two dot marks 22Y constituting each linear mark 22X are linearly arranged on a straight line so that the long axes 22a are directed in the direction of X-axis or Y-axis.

The dot marks 22Y constituting each linear mark 22X are distanced from each other by Sy4 or Sx4.

The second mark 24 is rectangular-shaped, and has two sides defining the length A4 extending in the direction of X-axis and two sides defining the length B4 extending in the direction of Y-axis.

The size of the overlay inspection mark 20 will be described below.

Although data is not shown, if the length L4 of each dot mark 22Y is longer than 16 μm, there is a possibility that the dot marks 22Y may break or separate from the surface of the layer. Therefore, the length L4 of each dot mark 22Y is preferably shorter than or equals to 16 μm.

Practically, the length L4 of the dot mark 22Y is preferably, for example, 15 μm, with a margin of resolution error at the current process node and a film residue after the etching process. In the configuration example shown in FIG. 5B, the length L4 of the dot mark 22Y is 10 μm. In this case, the width W4 of the dot mark 22Y is preferably, for example, 5.5 μm.

The distance Sy4 between the adjacent dot marks 22Y constituting each linear marks 22X is preferably, for example, 2 μm.

In this case, the distance (X4-W4=Y4-W4) between the linear marks 22X that face each other across the center point C is preferably, for example, 25 μm. X4 denotes the pitch at which two linear marks 22X are arranged in the direction of X-axis. Y4 denotes the pitch at which two linear marks 22X are arranged in the direction of Y-axis.

The length A4 of the second mark 24 in the direction of X-axis and the length B4 of the second mark 24 in the direction of Y-axis are preferably the same as each other.

Further, the length A4=B4 is preferably, for example, 15 μm.

The width W4 and the distances X4-W4 and Y4-W4 are not limited to the above described examples, but can be arbitrarily determined in consideration of the process node or the like, as long as the length L4 of the dot mark 22 is shorter than or equals to 16 μm.

As described above, even when the heat treatment is carried out in the manufacturing process of the semiconductor device, and even when the adhesion between the overlay inspection mark 20 and the surface of the layer is weakened, it becomes possible to prevent the breakage or separation of the overlay inspection mark 20. Accordingly, the exposing process can be carried out effectively and accurately.

### <Configuration Example of Ferroelectric Memory Device>

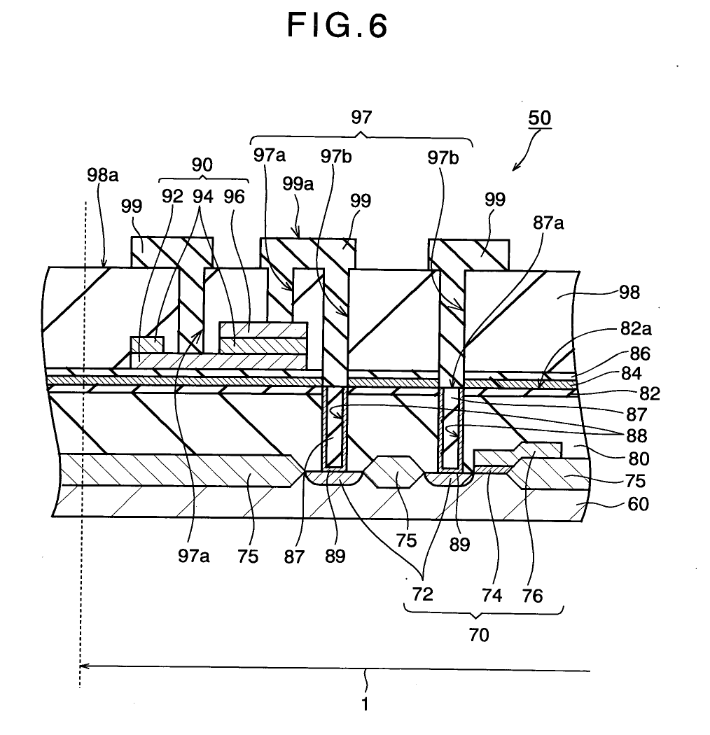

A configuration example of a ferroelectric memory device to which the alignment mark and the overlay inspection mark of the present invention are applicable (in the manufacturing process thereof) will be described with reference to FIG. 6.

FIG. 6 is a sectional view schematically showing the ferroelectric memory device.

As shown in FIG. 6, the ferroelectric memory device 50 is in the form of a semiconductor chip.

The ferroelectric memory device 50 is formed on the semiconductor substrate (wafer) 60. The semiconductor substrate 60 has a memory cell array region 1.

Memory cell elements (i.e., semiconductor elements) 70 are formed on the memory cell array region 1. The memory cell elements 70 are separated from each other by a conventional element-isolation structure such as a field oxide layer formed by LOCOS (Local Oxidation Of Silicon) method.

The memory cell elements 70 include transistors or other elements having the conventional structures. Each memory cell element 70 includes a memory cell diffusion region 72, a memory cell gate insulation film (a gate oxide film) 74 and a memory cell gate electrode 76 formed on the memory cell gate insulation film 74.

The memory cell diffusion region 72 is, for example, an ion diffusion region in which arbitrary suitable ion is implanted under conventional conditions. The memory cell gate insulation film 74 is, for example, a silicon oxide film formed by conventional thermal oxidation process. The memory cell gate electrode 76 is, for example, a conventional metal electrode.

A first insulation film 80 is formed on the memory cell array region 1 in which the memory cell elements 70 are formed. The first insulation film 80 is formed to cover the entire surface of the semiconductor substrate 60 on which the memory cell elements 70 are formed.

The first insulation film 80 is preferably formed of, for example, O₃-TEOS (Tetraethylorthosilicate)-based BPSG (Boro-Phospho Silicate Glass) film, manufactured by a CVD (Chemical Vapor Deposition) method using TEOS as material and using ozone (O₃).

An insulation film 82 is formed on the first insulation film 80. The insulation film 82 is preferably formed of, for example, P-TEOS film.

First contact holes 88 are formed on the first insulation film 80 and the insulation film 82. The first contact holes 88 penetrate the first insulation film 80 and the insulation film 82 and reach the memory cell elements 70.

It is also possible to form a metal film 89 on the surface (i.e., an inner surface and a bottom surface) of each first contact hole 88 as shown in FIG. 6. The metal film 89 functions as an adhesion layer.

The metal film 89 is preferably formed of, for example, titan nitride (TiN) firm, cobalt (Co) film, or Tantalum (Ta) film.

The first contact holes 88 (in which the metal films 89 are provided) are filled with conductive material such as tungsten (W), so that plugs 87 are formed. The top surfaces 87a of the plugs 87 are at the same height as a surface 82a of the insulation film 82.

An insulation film 84 is formed on the insulation film 82. The insulation film 84 is preferably formed of, for example, silicon nitride film (SiₓN_{y}: Si₃N₄).

The insulation film 84 is provided for protecting the plugs 87 which may otherwise be oxidized by the heat treatment at high temperature (referred to as a recovery annealing). The recovery annealing is generally carried out for recovering the properties of a ferroelectric layer 94 described later.

A second insulation film 86 is formed on the insulation film 84. The second insulation film 86 is preferably formed of, for example, tantalum oxide film (TaₓO_{y}: Ta₂O₅). The second insulation film 86 functions as an adhesion layer for lower electrodes 92 described later.

Ferroelectric capacitor structures 90 are formed on the second insulation film 86 of the memory cell array region 1.

The ferroelectric capacitor structure 90 has a layered structure including a lower electrode 92, a ferroelectric layer 94 and an upper electrode 96.

The lower electrode 92 and the upper electrode 96 are preferably formed of, for example, platinum (Pt) electrodes. The ferroelectric layer 94 is preferably formed of, for example, lead zirconate titanate (PZT), La-doped PZT (PLZT) or SBT (SrBi₂Ta₂O₉).

A third insulation film 98 is formed to cover the ferroelectric capacitor structures 90. The third insulation film 98 is formed on the entire surface of the second insulation film 86. The third insulation film 98 is preferably formed of, for example, TEOS-Silicon oxide film.

Second contact holes 97 (i.e., capacitor contact holes 97a and plug contact holes 97b) are formed on the third insulation film 98. The capacitor contact holes 97a reach the ferroelectric capacitor structures 90 from the surface 98a of the third insulation film 98.

The plug contact holes 97b reach the plugs 87 (connected to the memory cell elements 70) from the surface 98a of the third insulation film 98.

A wiring layers 99 are formed on the surface 98a of the third insulation film 98. The wiring layers 99 fill the second contact holes 97. The wiring layers 99 are electrically connected to the plugs 87, the upper electrodes 96 and the lower electrodes 92.

### <Manufacturing Method of Ferroelectric Memory Device>

A manufacturing method of the ferroelectric memory device of FIG. 6 will be described.

First, the memory cell elements 70 are formed on the memory cell array region 1 of the semiconductor substrate 60 by means of a conventional wafer process.

For example, the field oxide film 75, i.e., the elements isolation structure, is formed using the LOCOS method.

Then, the memory cell gate insulation film 74 is formed. Further, the memory cell gate electrodes 76 are formed on the memory cell gate insulation film 74 using the conventional method.

Next, the first insulation film 80 is formed on the entire surface of the upper side of the semiconductor substrate 60. The first insulation film 80 is formed by the conventional method. Preferably, the first insulation film 80 is formed of O₃-TEOS-based BPSG film by means of the conventional CVD method using the TEOS as material and using ozone (O₃).

Then, the insulation film 82 is formed on the first insulation film 80 using the conventional method. The insulation film 82 is preferably formed of, for example, P-TEOS film (silicon oxide film) using the conventional CVD method.

Next, the first contact holes 88 are formed on the first insulation film 80 and the insulation film 82 so that the first contact holes 88 penetrate the first insulation film 80 and the insulation film 82, by means of the photolithography process using photo-resist and the etching process.

To be more specific, a first resist mask is formed on the insulation film 82 using the photolithography. In this process, the first resist mask includes resist patterns for forming the first contact holes 88 on the memory cell array region 1 (i.e., chip region), and also includes resist patterns for forming the first alignment mark 10 (FIG. 1) and the first mark 22 of the overlay inspection mark 20 (FIG. 3) on the margin region outside the memory cell array region 1. The shape and the size of the alignment mark 10 and the overlay inspection mark 20 are, for example, as described in the first embodiment.

Using the first resist mask, the first contact holes 88 are formed on the memory cell array region 1, and grooves (not shown) for forming the alignment mark 10 and the first mark 22 are formed on the margin region, by means of the etching process. The first contact holes 88 and the grooves penetrate the first insulation film 80 and the insulation film 82.

Next, an ion implanting process and a thermal diffusion process are performed on the surface of the semiconductor substrate 60 exposed through the first contact holes 88° by means of the conventional method. In the ion implanting process, the ion such as P⁺ or BF²⁺ is implanted on the exposed surface of the semiconductor substrate 60, using the conventional method. The implanted ion is diffused into the semiconductor substrate 60 in the thermal diffusion process. In the thermal diffusion process, it is preferred to perform heat treatment of, for example, at the temperature of approximately 1000° C. for approximately 10 seconds.

Then, the metal film 89 is formed in the first contact holes 88 by means of the conventional method. The metal film 89 is preferably formed of, for example, titan nitride (TiN), cobalt (Co) or tantalum (Ta) by means of the conventional method.

Further, the conductive material is embedded in the first contact holes 88 (whose inner surfaces are covered with the metal film 89) by means of the conventional method. The conductive material such as tungsten (W) embedded in the first contact holes 88 form the plugs 87. In this process, the grooves for forming the alignment mark 10 and the first mark 22 are also embedded with the conductive material. Therefore, the alignment mark 10 and the first mark 22 are formed at the same time with the plugs 87.

Then, the insulation film 84 is formed to cover the entire exposed surface, i.e., the surface 82a of the insulation film 82 and the top surfaces 87a of the plugs 87. The insulation film 84 is preferably formed of, for example, silicon nitride film.

Next, the second insulation film 86 is formed on the insulation film 84. The second insulation film 86 is preferably formed of, for example, tantalum oxide film. The second insulation film 86 is preferably formed by a conventional sputtering method using tantalum (Ta) as the target and mixed gas of Argon (Ar)/Oxygen (O₂) as the process gas.

Then, layers for forming the ferroelectric capacitor structures 90 are formed on the second insulation film 86.

To be more specific, a platinum film or the like (for forming the lower electrode 92), an SBT film (for forming the ferroelectric layer 94), and a platinum film of the like (for forming the upper electrode 96) are layered using conventional method, so as to form a layered structure.

The platinum film is formed to an arbitrary suitable thickness by means of, for example, the sputtering method using platinum as the target and argon gas as the process gas. The SBT film is formed by a conventional method in which the spin coating process and the sintering process are repeated until the thickness of the SBT film reaches the predetermined thickness.

Then, a second resist mask is formed on the layered structure for forming the ferroelectric capacitor structures 90. In this process, the alignment mark 22 (having been formed on the first insulation film 80 and the insulation film 82) is used to adjust the exposing position for patterning the second resist mask. To be more specific, the exposing position is adjusted in accordance with the alignment mark 10 detected by the optical imaging device (for example, CCD camera) provided in the exposing device. Then, the exposure is performed, so that the second resist mask is patterned.

The second resist mask includes resist patterns for forming at least one of the lower electrode 92, the ferroelectric layer 94, and the upper electrode 96. In addition, the second resist mask also includes the second mark 24 of the overlay inspection mark 20 (FIG. 3) in the margin region.

After the second resist mask is formed, the positional relationship between the first mark 22 and the second mark 24 is measured using the overlay measuring apparatus. If the overlay of the first and second resist masks is successfully carried out, the second mark 24 is supposed to be on the predetermined position in the vicinity of the center point C of the first mark 22 formed on the first insulation film 80 and the insulation film 82.

If the positional relationship between the first mark 22 and the second mark 24 is within an allowable range, the process proceeds to the next step. If the positional relationship between the first mark 22 and the second mark 24 has a deviation beyond an allowable range, the second resist mask is completely removed. Further, the forming process of the second resist mask is repeated in accordance with the amount of deviation of the first mark 22 and the second mark 24 (i.e., the overlay inspection mark 20).

In this regard, the alignment mark 10 and the first mark 22 can be observed through the insulation film 84, the second insulation film 86, the lower electrode 92, the ferroelectric layer 94 and the upper electrode 96.

Next, using the second resist mask, at least one layer of the layered structure (for forming the ferroelectric capacitor structures 90) is patterned by means of the photolithography process and the etching process, so as to form the ferroelectric capacitor structures 90 on the second insulation film 86. In this regard, the ferroelectric capacitor structures 90 are arranged in a matrix in the memory cell array region 1.

Additionally, the second resist pattern further includes resist patterns for forming an additional alignment mark 10 and an additional first mark 22 of an additional overlay inspection mark 20 according to the second embodiment on the margin region. Therefore, when the ferroelectric capacitor structures 90 are formed (patterned), the additional alignment mark 10 and the additional first mark 22 are also formed. The additional alignment mark 10 and the additional first mark 22 have the same layered structures as the ferroelectric capacitor structures 90 (i.e., the lower electrode 92, the ferroelectric layer 94 and the upper electrode 96).

After the ferroelectric capacitor structures 90 are formed, the recovery annealing process is carried out. To be more specific, the heat treatment is performed under the oxygen (O) atmosphere at the temperature of 600 to 750° C. for a period from 0.5 hour to 1 hour. With this process, the electric properties having been degraded by the plasma damage during the etching process can be recovered.

Next, the third insulation film 98 is formed to cover the ferroelectric capacitor structures 90. The third insulation film 98 is, for example, a silicone oxide film formed of TEOS. The third ferroelectric capacitor structures 90 can be formed by the conventional plasma CVD method.

Then, a third resist mask is formed on the third insulation film 98. In this process, the additional alignment mark 10 (having been formed on the second insulation film 86) is used to adjust the exposing position for patterning the third resist mask. To be more specific, the exposing position is adjusted in accordance with the additional alignment mark 10 detected by the optical imaging device, and the exposure is performed so that the resist mask is patterned.

The third resist mask includes resist patterns for forming the second contact holes 97 in the memory cell array region 1. In addition, the third resist mask also includes an additional second mark 24 (FIG. 3) in the margin region.

After the third resist mask is formed, the positional relationship between the additional first mark 22 and the additional second mark 24 is measured using the overlay measuring apparatus.

If the positional relationship between the additional first mark 22 and the additional second mark 24 is within an allowable range, the process proceeds to the next step. If the positional relationship between the additional first mark 22 and the additional second mark 24 has a deviation beyond an allowable range, the third resist mask is completely removed. Further, the forming process of the third resist mask is repeated in accordance with the amount of deviation of the additional first mark 22 and the additional second additional mark 24 (i.e., the additional overlay inspection mark 20).

In this regard, it is also possible to use the additional alignment mark 10 and the additional overlay inspection mark 20 for forming other components on the upper layer above the contact hole 97.

Then, using the third resist mask, the second contact holes 97 are formed on the third insulation film 98, by means of the conventional method using conventional photolithography process and the etching process. The contact holes 97 reach, for example, the ferroelectric capacitor structures 90 and the plugs 87.

Next, the second contact holes 97 are embedded with the wiring layers 99. To be more specific, the wiring layers 99 can be formed by patterning the above described aluminum alloy using the conventional photolithographic process and the etching process.

The wiring layers 99 are formed on the surface 98a of the third insulation film 98 so that the wiring layers 99 are electrically connected to the plugs 87 and the ferroelectric capacitor structures 90.

As described above, by applying the alignment mark and the overlay inspection mark of the present invention to the manufacturing method of the ferroelectric memory device (i.e., semiconductor device), it becomes possible to prevent the separation of the alignment mark and the overlay inspection mark and the generation of the crack reaching the memory cell array region (i.e., chip region) due to the recovery annealing process.

While the preferred embodiments of the present invention have been illustrated in detail, it should be apparent that modifications and improvements may be made to the invention without departing from the spirit and scope of the invention as described in the following claims.

According to the embodiments of the present invention, there is provided a manufacturing method of a semiconductor device including the steps of:
(A1) forming memory cell elements on a chip region of a semiconductor substrate having a margin region and the chip region;
(A2) forming a first insulation film on an entire surface of the semiconductor substrate;
(A3) forming a first resist mask including patterns for forming an alignment mark and a first mark of an overlay inspection mark on the margin region of the first insulation film, and patterns for forming contact holes on the chip region of the first insulation film;
(A4) forming grooves for forming the alignment mark and the first mark on the margin region of the first insulation film and contact holes reaching the memory cell elements through the first insulation film, using the first resist mask;
(A5) forming the plugs, the alignment mark and the first mark by embedding the contact holes and the grooves with conductive material;
(A6) forming a second insulation film on the first insulation film;
(A7) forming a layered structure for forming a ferroelectric capacitor structure on the second insulation film;
(A8) forming a second resist mask, while adjusting the exposing position based on the alignment mark using an optical imaging device, the second resist mask including a second mark of the overlay inspection mark on the margin region of the second insulation film and a pattern for forming at least one layer of the ferroelectric capacitor structure on the chip region of the second insulation film, the second mark having the shape and size that enable the measurement of a positional relationship between the first mark and the second mark,

the second resist mask further including patterns for forming an additional alignment mark and an additional first mark of an additional overlay inspection mark on the margin region of the second insulation film;
(A9) measuring the positional relationship between the first mark and the second mark using the optical imaging device;
(A10) patterning at least one layer of the layered structure for forming the ferroelectric capacitor structure using the second resist mask, in the case where a deviation between the first mark and the second mark is within a predetermined range, so as to form the ferroelectric capacitor structure on the chip region of the second insulation film, as well as the additional alignment mark and the additional first mark of the additional overlay inspection mark (having the same layered structure as the ferroelectric capacitor structure) on the margin region of the second insulation film;
(A11) forming a third insulation film to cover the ferroelectric capacitor structure;
(A12) forming a third resist mask, while adjusting the exposing position based on the additional alignment mark using the optical imaging device, the third resist mask including a pattern for forming an additional second mark of the additional overlay inspection mark on the margin region of the third insulation film, the additional second mark having the shape and size that enable the measurement of a positional relationship between the additional first mark and the additional second mark; and
(A13) performing heat treatment to the ferroelectric capacitor structure.

Regarding the above described step (A3), the alignment mark includes a plurality of strip-shaped patterns having long axes and short axes and arranged in a matrix of rows and columns in such a manner that the long axes are substantially perpendicular to the direction of alignment adjustment. Further, the overlay inspection mark includes the first mark and the second mark. The first mark includes four linear marks each of which includes a plurality of strip-shaped dot marks having long axes and short axes. The dot marks of each linear mark are so disposed that long axes are directed in the same direction. The linear marks are disposed on four sides of a square in such a manner that two of the linear marks face parallel to each other across a center point of the square, and the other two of the linear marks face parallel to each other across the center point.

Regarding the above described step (A8), the additional alignment mark has the same shape as the alignment mark of the step (A3), and the additional first mark of the additional overlay inspection mark has the same shape as the first mark of the overlay inspection mark of the step (A3).

Further, the manufacturing method can further include the step (A14) of forming a metal film that covers inner surfaces of the contact holes, after the step (A4) forming the contact holes, and before the step (A5) forming the plugs.

According to another aspect of the present invention, there is provided a manufacturing method of a semiconductor device including the steps of:
(B1) forming memory cell elements on a chip region of a semiconductor substrate having a margin region and the chip region;
(B2) forming an insulation film on an entire surface of the semiconductor substrate;
(B3) forming a first resist mask including a pattern for forming an alignment mark on the margin region of the first insulation film, and patterns for forming contact holes on the chip region of the first insulation film;
(B4) forming a groove for forming the alignment mark on the margin region of the insulation film and contact holes reaching the memory cell elements through the first insulation film, using the first resist mask;
(B5) forming the plugs and the alignment mark by embedding the contact holes and the groove with conductive material;
(B6) forming a second insulation film on the first insulation film;
(B7) forming a layered structure for forming a ferroelectric capacitor structure on the second insulation film; and
(B8) forming a second resist mask, while adjusting the exposing position based on the alignment mark using an optical imaging device.

Regarding the step (B3), the alignment mark includes a plurality of strip-shaped patterns having long axes and short axes and arranged in a matrix of rows and columns in such a manner that the long axes are substantially perpendicular to the direction of alignment adjustment.

According to still another aspect of the present invention, there is provided a manufacturing method of a semiconductor device including the steps of:
(C1) forming memory cell elements on a chip region of a semiconductor substrate having a margin region and the chip region;
(C2) forming a first insulation film on an entire surface of the semiconductor substrate;
(C3) forming a first resist mask including a pattern for forming a first mark of an overlay inspection mark on the margin region of the first insulation film and patterns for forming contact holes on the chip region of the first insulation film;
(C4) forming a groove for forming the first mark of the overlay inspection mark on the margin region of the insulation film and a plurality of contact holes reaching the memory cell elements through the insulation film, using the first resist mask;
(C5) forming the plugs and the first mark of the overlay inspection mark by embedding the contact holes and the groove with conductive material;
(C6) forming a second insulation film on the first insulation film;
(C7) forming a layered structure for forming a ferroelectric capacitor structure on the second insulation film; and
(C8) forming a second resist mask including a second mark of the overlay inspection mark on the margin region of the second insulation film and a pattern for forming at least one layer of the ferroelectric capacitor structure on the chip region of the second insulation film, the second mark having the shape and size that enable the measurement of a positional relationship between the first mark and the second mark;
(C9) measuring the positional relationship between the first mark and the second mark using the optical imaging device; and
(C10) patterning at least one layer of the layered structure for forming the ferroelectric capacitor structure using the second resist mask in the case where a deviation between the first mark and the second mark is within a predetermined range.

In the step (C3), the overlay inspection mark includes the first mark and a second mark. The first mark includes four linear marks each of which includes a plurality of strip-shaped dot marks having long axes and short axes. The dot marks of each linear mark are so disposed that long axes are directed in the same direction. The linear marks are disposed on four sides of a square in such a manner that two of the linear marks face parallel to each other across a center point of the square, and the other two of the linear marks face parallel to each other across the center point.

According to yet another aspect of the present invention, there is provided a manufacturing method of a semiconductor device including the steps of:
(D1) forming memory cell elements on a chip region of a semiconductor substrate having a margin region and the chip region;
(D2) forming an insulation film on an entire surface of the semiconductor substrate;
(D3) forming a layered structure on the insulation film for forming a ferroelectric capacitor structure;
(D4) forming a first resist mask including a pattern for forming an alignment mark on the margin region of the insulation film and a pattern for forming a ferroelectric capacitor structure on the chip region of the insulation film,
(D5) forming the ferroelectric capacitor structure on the chip region of the insulation film and the alignment mark (having the same layered structure as the ferroelectric capacitor structure) on the margin region of the insulation film, using the first resist mask;
(D6) forming a second resist mask, while adjusting the exposing position based on the alignment mark using an optical imaging device; and
(D8) performing heat treatment to the ferroelectric capacitor structure.

In the step (D4), the alignment mark includes a plurality of strip-shaped patterns having long axes and short axes and arranged in a matrix of rows and columns in such a manner that the long axes are substantially perpendicular to the direction of alignment adjustment.

According to further aspect of the present invention, there is provided a manufacturing method of a semiconductor device including the steps of:
(E1) forming memory cell elements on a chip region of a semiconductor substrate having a margin region and the chip region;
(E2) forming an insulation film on an entire surface of the semiconductor substrate;
(E3) forming a layered structure for forming a ferroelectric capacitor structure on the insulation film;
(E4) forming a first resist mask including a pattern forming a first mark of an overlay inspection mark on the margin region of the insulation film and a pattern for forming a ferroelectric capacitor structure on the chip region of the insulation film,
(E5) forming the ferroelectric capacitor structure on the chip region of the insulation film and the first mark of the overlay inspection mark on the margin region of the insulation film, using the first resist mask;
(E6) forming a second insulation film on the first insulation film;
(E7) forming a second resist mask including a second mark of the overlay inspection mark in the margin region, the second mark having the shape and size that enable the measurement of a positional relationship between the first mark and the second mark;
(E9) measuring the positional relationship between the first mark and the second mark using the optical imaging device;
(E10) patterning at least one layer of the layered structure for forming the ferroelectric capacitor using the second resist mask in the case where a deviation between the first mark and the second mark is within a predetermined range, and
(E11) performing heat treatment to the ferroelectric capacitor structure.

In the step E4, the additional overlay inspection mark includes a first mark and a second mark. The first mark includes four linear marks each of which includes a plurality of strip-shaped dot marks having long axes and short axes. The dot marks of each linear mark are so disposed that long axes are directed in the same direction. The linear marks are disposed on four sides of a square in such a manner that two of the linear marks face parallel to each other across a center point of the square, and the other two of the linear marks face parallel to each other across the center point.

What is claimed is:

1. An alignment mark formed on an underlying layer and disposed on a region in which a semiconductor element is not formed,
said alignment mark comprising a plurality of strip-shaped patterns detectable by an optical imaging device,
wherein said patterns have long axes and short axes, and said patterns are arranged in a matrix of rows and columns in such a manner that said long axes are substantially perpendicular to the direction of the alignment adjustment.

2. The alignment mark according to claim 1, wherein each of said long axes is shorter than or equals to 16 μm.

3. The alignment mark according to claim 1, wherein each of said long axes is shorter than or equals to 10 μm.

4. The alignment mark according to claim 1, wherein each of said long axes is 15 μm and each of said short axes is 1 μm, and
wherein the distance between said patterns is 2 μm in the direction of said long axes and 5 μm in the direction of said short axes.

5. The alignment mark according to claim 4, wherein said patterns are arranged in a matrix of 4 rows and 18 columns.

6. The alignment mark according to claim 1, wherein each of said long axes is 4 μm and each of said short axes is 1 μm, and
wherein the distance between said patterns is 4 μm in the direction of said long axes and 5 μm in the direction of said short axes.

7. The alignment mark according to claim 6, wherein said patterns are arranged in a matrix of 7 rows and 18 columns.

8. An overlay inspection mark formed on an underlying layer and disposed on a region in which a semiconductor element is not formed,
said overlay inspection mark comprising a first mark and a second mark both of which are detectable by an optical imaging device,
wherein said first mark includes four linear marks each of which includes a plurality of strip-shaped dot marks having long axes and short axes, said dot marks of each of said linear marks being so disposed that said long axes are directed in the same direction,
wherein said linear marks are disposed on four sides of a square in such a manner that two of said linear marks face parallel to each other across a center point of said square, and the other two of said linear marks face parallel to each other across said center point, and
wherein said second mark has a shape and a size that enable the measurement of a positional relationship between said first mark and said second mark.

9. The overlay inspection mark according to claim 8, wherein each of said long axes of said dot marks is shorter than or equals to 16 μm.

10. The overlay inspection mark according to claim 8, wherein each of said long axes of said dot marks is shorter than or equals to 10 μm.

11. The overlay inspection mark according to claim 8, wherein each of said linear marks includes two dot marks having said long axes of 15 μm and said short axes of 5.5 μm, and the distance between said two dot marks is 2 μm in the direction of said long axes, and
wherein the distance between said linear marks facing each other across said center point is 25 μm.

12. The overlay inspection mark according to claim 8, wherein each of said linear marks includes four dot marks having said long axes of 4 μm and said short axes of 2 μm, and the distance between said dot marks is 4 μm in the direction of said long axes, and
wherein the distance between said linear marks facing each other across said center point is 40 μm.

13. The overlay inspection mark according to claim 8, wherein said second mark has a rectangular shape surrounded by said linear marks.
